(19) United States
(12) Patent Application Publication
(10) Pub. No.: US 2014/0175425 A1
(43) Pub. Date: Jun. 26, 2014

(54) THIN FILM TRANSISTOR

(71) Applicant: Hon Hai Precision Industry Co., Ltd., New Taipei (TW)

(72) Inventor: JIAN-SHIHN TSANG, New Taipei (TW)

(73) Assignee: Hon Hai Precision Industry Co., Ltd., New Taipei (TW)

(21) Appl. No.: 14/011,717

(22) Filed: Aug. 27, 2013

(30) Foreign Application Priority Data
Dec. 26, 2012 (TW) 101149942

(51) Int. Cl. H01L 29/786

(52) U.S. Cl. CPC H01L 29/78693
USPC 257/43

(57) ABSTRACT

A thin film transistor includes a substrate and a gate electrode formed on the substrate. A gate insulating layer is formed on the substrate and covers the gate electrode. A channel layer is formed on the gate insulating layer. A GaZnO layer formed on the channel layer. A source electrode and a drain electrode are formed on two opposite ends of the GaZnO layer, respectively.

### BACKGROUND

1. Technical Field

The disclosure generally relates to a thin film transistor.

2. Description of Related Art

Nowadays, thin film transistors have been widely used in display devices to make the display devices become thinner and smaller. A typical thin film transistor includes a channel layer, a gate electrode, a source electrode and a drain electrode formed on the channel layer. The thin film transistor is turned on or turned off by controlling a voltage applied to the gate electrode.

Thin film transistors made of indium gallium zinc oxide (IGZO) material have been widely used in liquid crystal display panels, especially in liquid crystal display panels with a high resolution and a large size. However, IGZO films are easy to be affected by temperature, oxygen content, steam or illumination in outer environment. Therefore, parameters such as current on-off ratio, surface carriers concentration of the IGZO thin film transistor are also affected and a quality of the thin film transistor is reduced.

What is needed, therefore, is a thin film transistor to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional view of a thin film transistor in accordance with a first embodiment of the present disclosure.

FIG. 2 is cross sectional view of a GaZnO layer of the thin film transistor in FIG. 1.

FIG. 3 is a cross sectional view of a thin film transistor in accordance with a second embodiment of the present disclosure.

FIG. 4 is a cross sectional view of a thin film transistor in accordance with a third embodiment of the present disclosure.

### DETAILED DESCRIPTION

Embodiments of thin film transistors will now be described in detail below and with reference to the drawings.

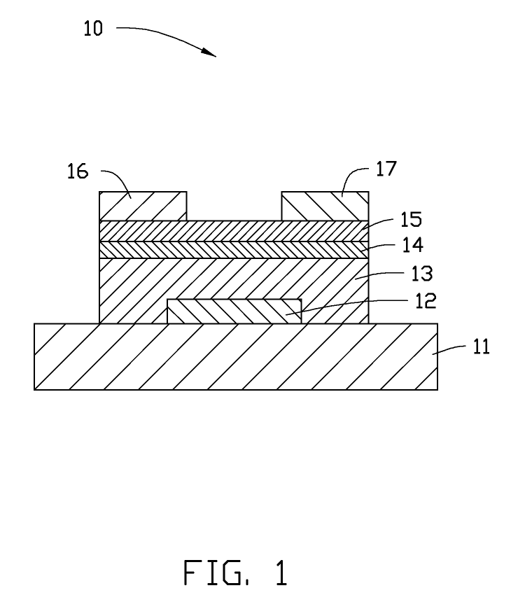

Referring to FIG. 1, a thin film transistor 10 in accordance with a first embodiment of the present disclosure is provided. The thin film transistor 10 includes a substrate 11, a gate electrode 12, a gate insulating layer 13, a channel layer 14, a GaZnO layer 15, a source electrode 16 and a drain electrode 17.

The substrate 11 is configured to support the gate electrode 12 and the gate insulating layer 13. The substrate 11 is made of a material selected from glass, quartz, silicon, polycarbonate, polymethyl methacrylate or metallic foil.

The gate electrode 12 is formed on an upper surface of the substrate 11. In this embodiment, the gate electrode 12 is located in a central portion of the substrate 11. The gate electrode 12 is made of a material selected from Cu, Al, Ni, Mg, Cr, Mo, W or alloys thereof.

The gate insulating layer 13 covers on the gate electrode 12. In this embodiment, the gate electrode 12 extends to contact the substrate 11. The gate insulating layer 13 is made of a material selected from SiOx, SiNx and SiONx, or insulating materials with a high dielectric constant such as Ta₂O₅ and HfO₂.

The channel layer 14 is formed on an upper surface of the gate insulating layer 13. In this embodiment, the channel layer 14 is made of IGZO semiconductor material.

The GaZnO layer 15 is formed on an upper surface of the channel layer 14. The source electrode 16 and the drain electrode 17 are respectively formed on two opposite ends of the GaZnO layer 15.

A thickness of the GaZnO layer 15 is larger than 0.5 nm. Preferably, the thickness of the GaZnO layer 15 is in a range from 0.5 nm to 100 nm. In this embodiment, the thickness of the GaZnO layer 15 is 20 nm.

A ratio of the thickness of the GaZnO layer 15 and a thickness of the channel layer 14 is in a range from 1:100 to 5:1. In this embodiment, the ratio of the thickness of the GaZnO layer 15 and the thickness of the channel layer 14 is 1:100 or 5:1.

The GaZnO layer 15 can be a single layer or multiple layers.

When the GaZnO layer 15 is a single layer, a concentration of Ga in the GaZnO layer 15 gradually increases in a direction away from the channel layer 14.

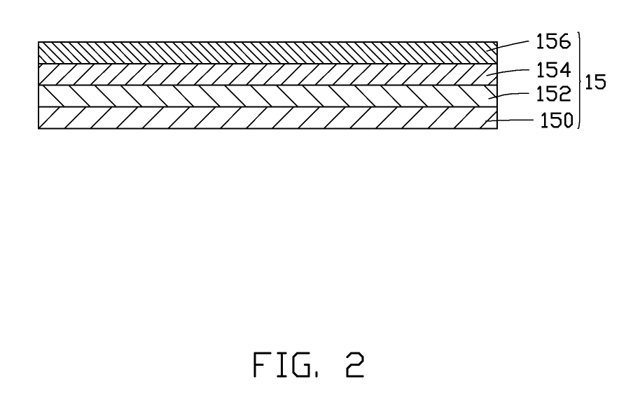

Referring also to FIG. 2, when the GaZnO layer 15 is multiple layers, the GaZnO layer 15 include a plurality of GaZnO semiconductor layers 150, 152, 154, 156. A concentration of Ga in each of GaZnO semiconductor layers 150, 152, 154, 156 is different from a concentration of Ga in others. Preferably, the concentration of Ga in the GaZnO layer 15 adjacent to the channel layer 14 is less than the concentration of Ga in the GaZnO layer 15 away from the channel layer 14. That is, the concentration of Ga in the GaZnO semiconductor layer 150 is less than the concentration of Ga in the GaZnO semiconductor layer 152; the concentration of Ga in the GaZnO semiconductor layer 152 is less than the concentration of Ga in the GaZnO semiconductor layer 154; the concentration of Ga in the GaZnO semiconductor layer 154 is less than the concentration of Ga in the GaZnO semiconductor layer 156.

In this embodiment, the GaZnO layer 15 totally covers the upper surface of the channel layer 14. The source electrode 16 and the drain electrode 17 are formed on the upper surface of the GaZnO layer 15. In this embodiment, a thickness of a central portion of the GaZnO layer 15 is equal to a thickness of lateral portions of the GaZnO layer 15 for supporting the source electrode 16 and drain electrode 17.

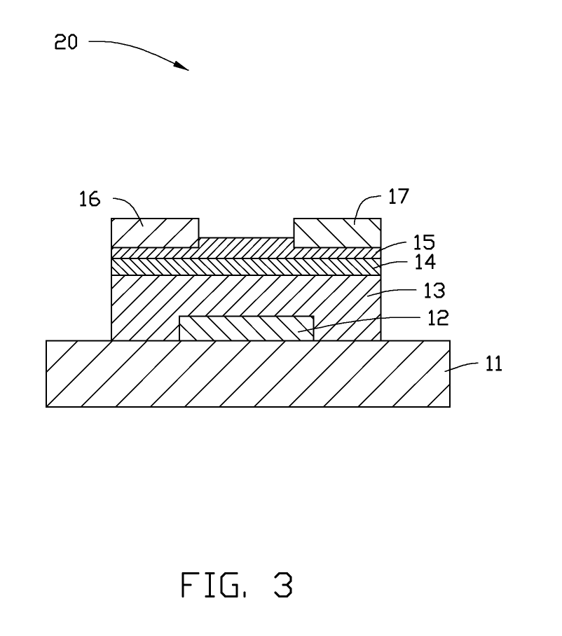

Referring to FIG. 3, a thin film transistor 20 in accordance with a second embodiment of the present disclosure is provided. The thin film transistor 20 includes the substrate 11, the gate electrode 12, the gate insulating layer 13, the channel layer 14, the GaZnO layer 15, the source electrode 16 and the drain electrode 17. Different from the first embodiment, a thickness of a central portion of the GaZnO layer 15 is larger than a thickness of lateral portions of the GaZnO layer 15 for supporting the source electrode 16 and the drain electrode 17.

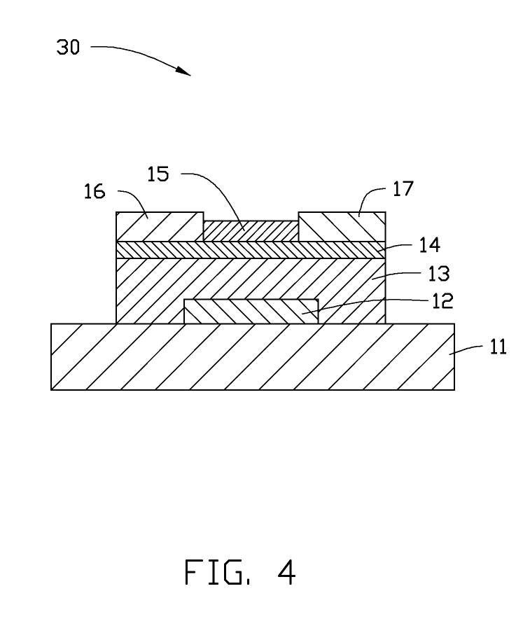

Referring to FIG. 4, a thin film transistor 30 in accordance with a third embodiment of the present disclosure is provided. The thin film transistor 30 includes the substrate 11, the gate electrode 12, the gate insulating layer 13, the channel layer 14, the GaZnO layer 15, the source electrode 16 and the drain electrode 17. Different from the first embodiment, the GaZnO layer 15 is located in a central portion of the upper surface of the channel layer 14. The source electrode 16 and the drain electrode 17 are also located on lateral portions of the upper surface of the channel layer 14.

In the thin film transistor 10, 20 and 30 described above, by forming the GaZnO layer 15 on the channel layer 14, since the GaZnO layer 15 does not have In ions, carriers can not form electrical conduction through 5 s electron orbit of In Ions. In addition, the Ga ions in the GaZnO layer 15 form a scattering center in crystal lattice and generates a deformation of the crystal structure of the GaZnO layer 15. Furthermore, the Ga ions can reduce the forming of oxygen vacancy, thereby reducing carrier concentration and surface leakage current of the thin film transistor 10, 20, and 30. Therefore, current on-off ratio of the thin film transistor 10, 20, 30 is improved.

In an alternative embodiment, the GaZnO layer 15 can be replaced by other metallic oxide semiconductor layer without In ions, such as AlZnO layer. It is just insure that the metallic oxide semiconductor layer has a relatively low carrier concentration. In this embodiment, when the metallic oxide semiconductor layer has a carrier concentration less than 10¹⁶ cm⁻³, the metallic oxide semiconductor layer formed on the channel layer 14 can obviously reduce the surface leakage current and improve the quality of the thin film transistor.

Furthermore, the GaZnO layer 15 is transparent to infrared light. When a thickness of the GaZnO layer 15 is 20 nm, transmissions of infrared light and light with a wavelength larger than 400 nm in the GaZnO layer 15 are not less than 60%. For infrared light with a relatively long wavelength, the transmission in the GaZnO layer 15 is near 100%. Therefore, the GaZnO layer 15 will not affect the properties of the liquid crystal display panel.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thin film transistor, comprising:
a substrate;
a gate electrode formed on the substrate;
a gate insulating layer formed on the substrate and covering the gate electrode;
a channel layer formed on the gate insulating layer;
a GaZnO layer formed on the channel layer; and
a source electrode and a drain electrode formed on two opposite ends of the GaZnO layer, respectively.

2. The thin film transistor of claim 1, wherein the GaZnO layer totally covers an upper surface of the channel layer, and the source electrode and the drain electrode are formed on an upper surface of the GaZnO layer.

3. The thin film transistor of claim 2, wherein a thickness of a central portion of the GaZnO layer is equal to a thickness of lateral portions of the GaZnO layer for supporting the source electrode and drain electrode.

4. The thin film transistor of claim 2, wherein a thickness of a central portion of the GaZnO layer is larger than a thickness of lateral portions of the GaZnO layer for supporting the source electrode and drain electrode.

5. The thin film transistor of claim 1, wherein the GaZnO layer is located in a central portion of an upper surface of the channel layer, the source electrode and the drain electrode are located at lateral portions of the upper surface of the GaZnO layer.

6. The thin film transistor of claim 1, wherein a thickness of the GaZnO layer is larger than 0.5 nm.

7. The thin film transistor of claim 1, wherein a ratio of a thickness of the GaZnO layer and a thickness of the channel layer is in a range from 1:100 to 5:1.

8. The thin film transistor of claim 1, wherein a concentration of Ga of the GaZnO layer gradually increases in a direction away from the channel layer.

9. The thin film transistor of claim 1, wherein the GaZnO layer comprises a plurality of GaZnO semiconductor layers, and a concentration of Ga in each of the GaZnO semiconductor layers is different from a concentration of Ga in others.

10. The thin film transistor of claim 1, wherein a concentration of Ga in a GaZnO semiconductor layer adjacent to the channel layer is less than a concentration of Ga in a GaZnO semiconductor layer away from the channel layer.

11. A thin film transistor, comprising:
a substrate;
a gate electrode formed on the substrate;
a gate insulating layer formed on the substrate and covering the gate electrode;
a channel layer formed on the gate insulating layer, the channel layer being made of InGaZnO material;
a metallic semiconductor layer formed on the channel layer, the metallic semiconductor layer not comprising In ions; and
a source electrode and a drain electrode formed on two opposite ends of the metallic semiconductor layer.

12. The thin film transistor of claim 11, wherein the metallic semiconductor layer is made of AlZnO material.

13. The thin film transistor of claim 11, wherein the metallic semiconductor layer comprises Ga ions.

14. The thin film transistor of claim 13, wherein a carrier concentration of the metallic semiconductor layer is less than 10¹⁶ cm⁻³.

15. The thin film transistor of claim 14, wherein metallic semiconductor layer is made of GaZnO material.

16. The thin film transistor of claim 15, wherein the metallic semiconductor layer is transparent to infrared light.

17. The thin film transistor of claim 16, wherein a transmission of infrared light in the metallic semiconductor layer is not less than 60%.
